(19) United States
(12) Patent Application Publication
(10) Pub. No.: US 2014/0140800 A1
(43) Pub. Date: May 22, 2014

(54) ROBOT ARM, ROBOT AND ROBOT OPERATING METHOD

(71) Applicant: KABUSHIKI KAISHA YASKAWA DENKI, Kitakyushu-shi (JP)

(72) Inventors: Hisaya INOUE, Fukuoka (JP); Satoshi SUEYOSHI, Fukuoka (JP)

(73) Assignee: KABUSHIKI KAISHA YASKAWA DENKI, Kitakyushu-shi (JP)

(21) Appl. No.: 14/080,675

(22) Filed: Nov. 14, 2013

(30) Foreign Application Priority Data
Nov. 16, 2012 (JP) 2012-252391

(51) Int. Cl. B25J 18/04; H01L 21/677

(52) U.S. Cl. CPC B25J 18/04; H01L 21/67742
USPC 414/744.5

(57) ABSTRACT

A robot arm includes an extensible/retractable arm unit, which is configured to extend and retract in a horizontal direction and provided with a pulley arranged in a tip end portion thereof, and a robot hand rotatably connected to the tip end portion of the extensible/retractable arm unit through the pulley. The robot arm further includes a belt drive device including one or more drive power sources, which are arranged close to the robot hand and configured to directly drive a belt wound around the pulley.

### CROSS-REFERENCE TO RELATED APPLICATION

The present disclosure contains subject matter related to that disclosed in Japanese Priority Patent Application No. 2012-252391 filed with the Japan Patent Office on Nov. 16, 2012, the entire contents of which are incorporated herein by reference.

### BACKGROUND OF THE INVENTION

1. Field of the Invention

Embodiments disclosed herein relate to a robot arm, a robot and a robot operating method.

2. Description of the Related Art

Conventionally, a horizontal articulated robot is known as a robot for transferring workpieces such as glass substrates and semiconductor wafers. The horizontal articulated robot is a robot including an extensible/retractable arm unit in which two arms are connected through a joint. In the horizontal articulated robot, a robot hand installed at a tip end portion of the extensible/retractable arm unit is linearly moved along a horizontal direction by rotationally operating the respective arms.

The rotating operation of each of the arms is performed by, e.g., transmitting a power of a single motor serving as a drive power source through a belt-pulley mechanism and rotating a pulley installed in the base end portion of each of the arms.

In this horizontal articulated robot, it is required that the orientation of the robot hand is not changed during the rotating operation of each of the arms. In this regard, there has been proposed, e.g., a method in which the orientation of the robot hand is restrained by installing a driven pulley in the base end portion of the robot hand and connecting the driven pulley to the aforementioned belt-pulley mechanism so as to rotate in reaction to the rotation of an arm.

In the case of using the belt-pulley mechanism, however, it is known that the power transmission rigidity is reduced due to the expansion, contraction and deflection of a belt. There have been proposed many different technologies for securing the power transmission rigidity (see, e.g., Japanese Utility model Application Publication No. H02-58151A).

In a power transmission device disclosed in Japanese Utility model Application Publication No. H02-58151A, a belt member stretched between a driving gear and a driven gear is partially or entirely reinforced by a reinforcing member such as a metal plate or the like.

However, a workpiece size is increased these days, and therefore, in the conventional case, there is a room for additional improvement in terms of securing the power transmission rigidity and reducing the transverse sway regardless of the size of a workpiece.

For example, the metal plate is used as the reinforcing member of the belt in the conventional case. However, if the belt reinforced with the reinforcing member having a high specific gravity is arranged in the horizontal direction, the length of the belt becomes larger as the length of the arm is significantly increased due to the size of the workpiece. As a result, the belt is easily deflected in the vertical direction. Accordingly, the technique of the conventional case is insufficient to secure the power transmission rigidity regardless of the size of the workpiece.

Further, as can be seen from the advent of a glass substrate for a liquid crystal panel having a width of 2 m or more, the workpiece size is remarkably increased in recent years. For that reason, as compared with the conventional case, it is highly likely that a large transverse sway is generated in the horizontal direction due to the load of the workpiece or other causes. In such a case, according to the conventional case, the belt needs to be strongly reinforced by, e.g., increasing the thickness of the metal plate. However, this poses a problem in that the belt becomes easily deflectable and the cost grows higher.

### SUMMARY OF THE INVENTION

In accordance with an aspect of the embodiments, there is provided a robot arm including: an extensible/retractable arm unit configured to extend and retract in a horizontal direction and provided with a pulley arranged in a tip end portion thereof; a robot hand rotatably connected to the tip end portion of the extensible/retractable arm unit through the pulley; and a belt drive device including one or more drive power sources, which are arranged close to the robot hand and configured to directly drive a belt wound around the pulley.

### BRIEF DESCRIPTION OF THE DRAWINGS

FIG. 1 is a schematic view showing a configuration of a robot according to an embodiment.

FIG. 2 is a schematic plan view showing an operation of the robot in which an extensible/retractable arm unit to extend.

FIG. 3A is a schematic plan view showing an internal configuration of a robot arm according to a first embodiment.

FIG. 3B is an enlarged view of an area designated by EV1 in FIG. 3A.

FIG. 4A is a block diagram showing a configuration of a control device.

FIG. 4B shows one example of the transverse sway correction information.

FIG. 5 is a schematic plan view showing an internal configuration of a robot arm according to a second embodiment.

FIG. 6 is a schematic plan view showing an internal configuration of a robot arm according to a third embodiment.

FIG. 7 is a schematic plan view showing a configuration of a belt disconnection sensing mechanism.

### DESCRIPTION OF THE EMBODIMENTS

Embodiments of a robot arm, a robot and a robot operating method disclosed in the subject application will now be described in detail with reference to the accompanying drawings. The present disclosure is not limited by the embodiments described herein below.

In the following description, a substrate transfer robot for transferring a glass substrate as a transfer target object will be described by way of example. The substrate transfer robot will be just referred to as “robot”. A robot hand as an end effector will be just referred to as “hand”. The glass substrate will be referred to as “workpiece”.

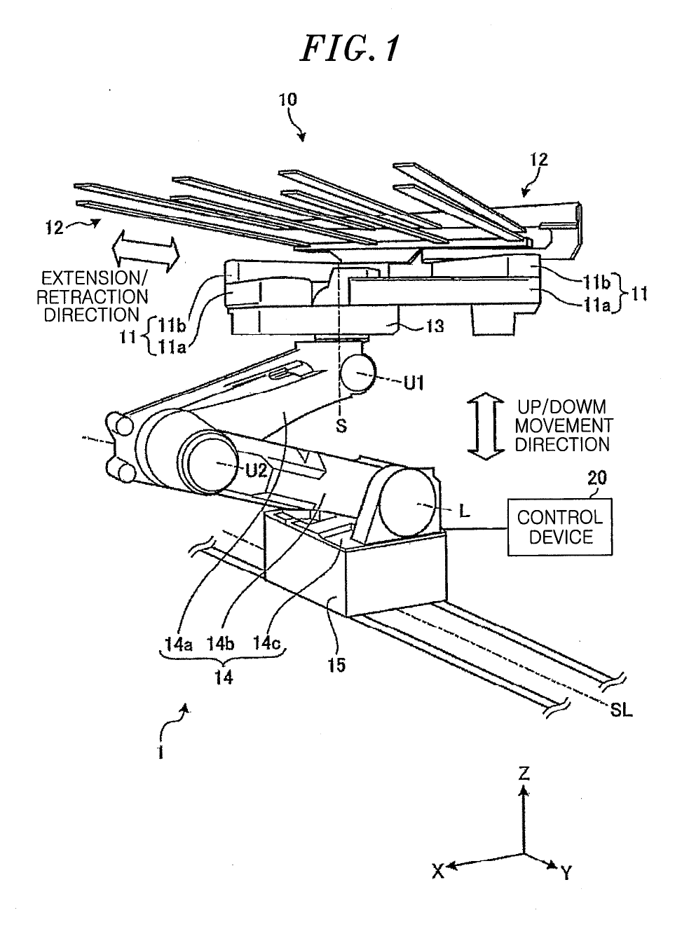

First, the configuration of a robot 10 according to the present embodiment will be described with reference to FIG. 1. FIG. 1 is a schematic view showing the configuration of the robot 10 according to the present embodiment.

For the sake of easier understanding of description, a three-dimensional rectangular coordinate system including a Z-axis whose positive direction is a vertical upward direction and whose negative direction is a vertical downward direction is indicated in FIG. 1. The direction running along an XY plane designates a “horizontal direction”. The rectangular coordinate system will be sometimes indicated in other drawings used in the following description. In the following description, the X-axis positive direction will be defined as “front” and the Y-axis positive direction will be defined as “left”.

In the following description, it is sometimes the case that, if there exists a plurality of components, some of the components are designated by reference symbols with the remaining components not designated by reference symbols. In this case, the component designated by a reference symbol is identical in configuration with the remaining components not designated by reference symbols.

The robot 10 shown in FIG. 1 is a dual-arm horizontal articulated robot including a pair of extensible/retractable arm units 11 which can be extended and retracted in an extension/retraction direction, i.e., in an X-axis direction. More specifically, the robot 11 includes a pair of extensible/retractable arm units 11, a pair of hands 12, an arm base 13, an elevating stand 14 and a running table 15.

Each of the extensible/retractable arm units 11 includes a first arm 11a and a second arm 11b. The elevating stand 14 includes a first elevator arm 14a, a second elevator arm 14b and a base portion 14c. A “robot arm” is configured to include at least the extensible/retractable arm units 11 and the hands 12.

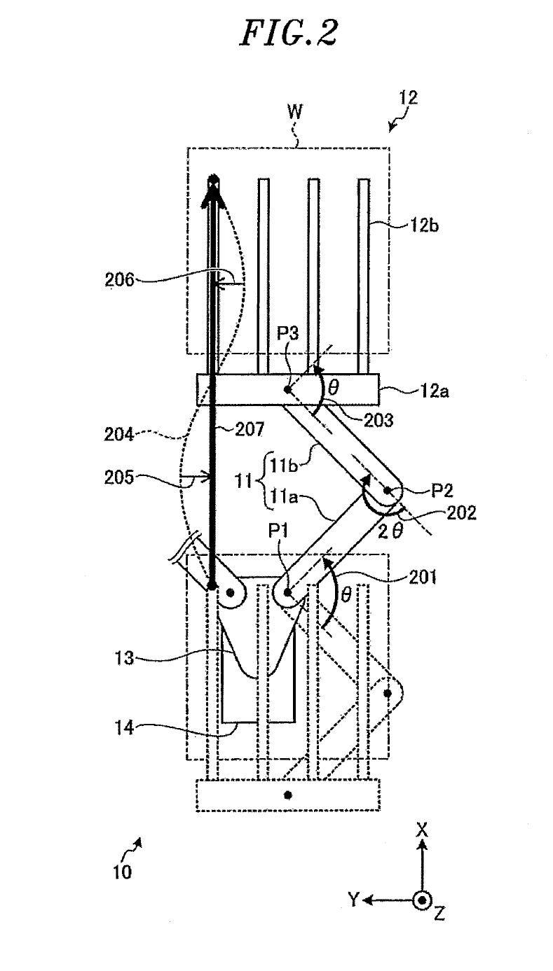

Each of the hands 12 is an end effector for holding a workpiece and is installed in a tip end portion of each of the extensible/retractable arm units 11. Details of the extensible/retractable arm units 11 and the hands 12 will be described later with reference to FIG. 2. The arm base 13 serves as a base portion of the extensible/retractable arm units 11 and supports the extensible/retractable arm units 11 in a horizontally rotatable manner.

The arm base 13 is connected to the elevating stand 14 to swing about a swing axis S parallel to the vertical direction. In the following description, the swing operation about the swing axis S will be sometimes referred to as “swing axis operation” of the robot 10.

The elevating stand 14 swingably supports the arm base 13 at a tip end portion thereof and moves the arm base 13 up and down along an up/down movement direction parallel to the vertical direction.

The first elevator arm 14a supports the arm base 13 in a tip end portion thereof so that the arm base 13 can swing about the swing axis S and can rotate about an axis U1. The second elevator arm 14b supports a base end portion of the first elevator arm 14a in a tip end portion thereof so that the first elevator arm 14a can rotate about an axis U2.

The base portion 14c is installed on the running table 15 to support a base end portion of the second elevator arm 14b so that the second elevator arm 14b can rotate about an axis L. The running table 15 is a running mechanism formed of a running carriage or the like. The running table 15 runs along, e.g., a running axis SL parallel to a Y-axis in FIG. 1. The running axis SL is not limited an axis having a linear shape. In the following description, the running operation along the running axis SL will be sometimes referred to as “running axis operation” of the robot 10.

The robot 10 performs an up/down operation by rotating the arm base 13 about the axis U1, the first elevator arm 14a about the axis U2, and the second elevator arm 14b about the axis L.

A control device 20 is connected to the robot 10 to make communications with the robot 10. The control device 20 controls the robot 10 to carry out various operations, such as the up/down operation, the swing axis operation, the running axis operation and an extension/retraction operation of each of the extensible/retractable arm units 11 which will be described later. A substrate transfer system 1 is configured to include at least the control device 20 and the robot 10.

Next, the extension/retraction operation of each of the extensible/retractable arm units 11 including the hands 12 will be described with reference to FIG. 2. FIG. 2 is a schematic plan view showing an operation of the robot 10 in which the extensible/retractable arm units 11 are made to extend.

For the sake of easier understanding of description, one of the extensible/retractable arm units 11 serving as dual arm, i.e., the extensible/retractable arm unit 11 corresponding to a right arm, will be shown and described herein below.

As shown in FIG. 2, a base end portion of the first arm 11a of the extensible/retractable arm unit 11 is connected to the arm base 13 so that the first arm 11a can rotate about an axis P1. A base end portion of the second arm 11b is connected to a tip end portion of the first arm 11a so that the second arm 11b can rotate about an axis P2.

A base end portion of the hand 12 is connected to a tip end portion of the second arm 11b so that the hand 12 can rotate about an axis P3. The hand 12 includes a frame 12a and a plurality of prongs 12b. The frame 12a is connected to the second arm 11b. The frame 12a supports the prongs 12b in parallel.

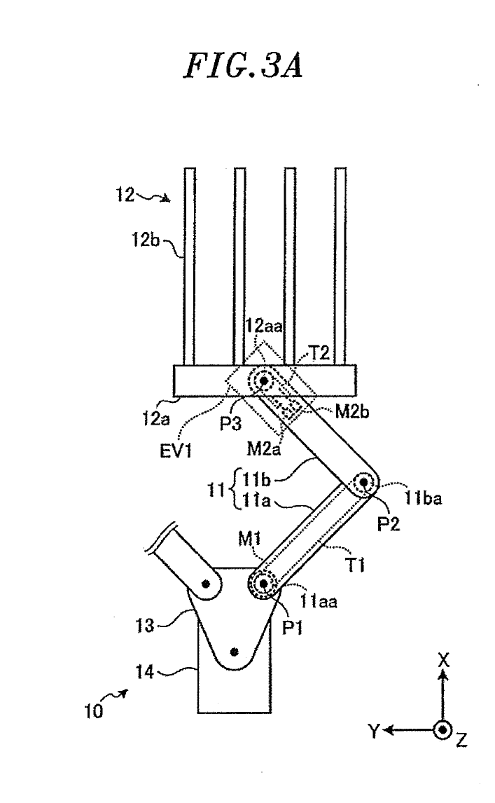

The second arm 11b and the frame 12a have a hollow structure. A belt drive device for rotating the hand 12 is arranged within the second arm 11b and the frame 12a. Description thereof will be made later in more detail with reference to FIG. 3A and subsequent drawings.

As shown in FIG. 2, the prongs 12b are members for holding a workpiece W and are configured to hold the workpiece W by supporting the workpiece W on main surfaces thereof, for example. The method for holding the workpiece W is not limited to the above example, and the prongs 12b may suck the workpiece W.

As shown in FIG. 2, when extending the extensible/retractable arm unit 11, the robot 10 performs an operation of extending the extensible/retractable arm unit 11 while restricting the moving direction and the orientation of the hand 12 to a specified moving direction and a specified orientation (to the X-axis positive direction in FIG. 2).

More specifically, when extending the extensible/retractable arm unit 11, the robot 10 rotates the first arm 11a counterclockwise by a rotation amount θ about the axis P1 (see the arrow 201 in FIG. 2). At this time, the second arm 11b is rotated clockwise by a double rotation amount 2θ about the axis P2 with respect to the first arm 11a (see the arrow 202 in FIG. 2).

The hand 12 is rotated counterclockwise by a rotation amount θ about the axis P3 with respect to the second arm 11b (see the arrow 203 in FIG. 2). These are basic rotation operations for extending the extensible/retractable arm unit 11 while restricting the moving direction of the hand 12 to the direction linearly extending along the X-axis and restricting the orientation of the hand 12 (i.e., the orientation of tip end portions of the prongs 12b) to the front side.

Conventionally, the rotation operations are performed by transmitting a power of a single drive power source arranged in the arm base 13 or the like to the axis P2 or the axis P3 through a belt-pulley mechanism. However, if only the basic rotation operations are performed in the conventional case, the transverse sway as indicated by a dotted-line trajectory 204 in FIG. 2 is highly likely to occur because the power transmission rigidity of a belt may be low, and further there may be an increased chance for the hand 12 to hold a large workpiece W.

Accordingly, in the present embodiment, the transverse sway is reduced by correcting the rotation operations of the hand 12 in specified positions (see the arrows 205 and 206 in FIG. 2), thereby taking a measure for reliably restricting the moving direction and the orientation of the hand 12 (see the arrow 207).

Next, first to third embodiments as specific examples of such a measure will be described one after another with reference to FIGS. 3A to 6.

### First Embodiment

FIG. 3A is a schematic plan view showing an internal configuration of a robot arm according to a first embodiment. FIG. 3B is an enlarged view of an area designated by EV1 in FIG. 3A. For the sake of convenience in description, FIG. 3B depicts X′ and Y′ axes obtained by rotating the X and Y axes in conformity with the extension direction of the second arm 11b.

As shown in FIG. 3A, the first arm 11a of the robot 10 according to the first embodiment is provided, in the base end portion thereof, with a driving pulley 11aa whose rotation axis coincides with the axis P1. The driving pulley 11aa is connected to an output shaft of a motor M1 installed within the arm base 13. The motor M1 is a drive power source for rotating the first arm 11a about the axis P1 by way of the driving pulley 11aa.

The second arm 11b is provided, in the base end portion thereof, with a driven pulley 11ba whose rotation axis coincides with the axis P2. The second arm 11b is connected to the first arm 11a through the driven pulley 11ba so that the second arm 11b can relatively rotate with respect to the rotation of the first arm 11a.

The driven pulley 11ba and the driving pulley 11aa are connected to each other through a belt T1. Therefore, the second arm 11b is passively rotated about the axis P2 by the driven pulley 11ba that receives the power of the motor M1 through the belt T1.

The hand 12 is connected to the tip end portion of the second arm 11b through a pulley 12aa installed in the tip end portion of the second arm 11b so that the hand 12 can rotate about the axis P3.

As depicted in a rectangular dotted-line area designated by EV1 in FIG. 3A, the second arm 11b includes a belt drive device having two motors, i.e., a first motor M2a and a second motor M2b, each serving as a drive power source for a belt T2 arranged close to the hand 12 (i.e., within the tip end portion of the second arm 11b). The belt drive device is a mechanism that rotates the hand 12 about the axis P3 by driving the belt T2 wound around the pulley 12aa in the tip end portion of the second arm 11b.

The belt drive device will now be described in detail. As shown in FIG. 3B, the belt drive device includes two motors M2a and M2b and two ball screws, i.e., a first ball screw B2a and a second ball screw B2b.

The motors M2a and M2b respectively include output shafts O1 and O2 arranged to extend along the extension direction of the second arm 11b (in the X′-axis direction in FIG. 3B). The ball screws B2a and B2b are respectively connected to the output shafts O1 and O2.

By arranging the motors M2a and M2b such that the output shafts O1 and O2 thereof extend along the extension direction of the second arm 11b, it becomes possible to reduce the thickness of at least the second arm 11b. This assists in reducing the size of the robot 10 and narrowing the operation space.

One end of the belt T2 wound around the pulley 12aa is fixed to a nut N2a of the ball screw B2a. The other end of the belt T2 is fixed to a nut N2b of the ball screw B2b.

In the configuration described above, the motors M2a and M2b are independently driven and controlled to adjust the rotation amount of the pulley 12aa, the rotation direction of the pulley 12aa (see the arrow 305 in FIG. 3B) and the tension of the belt T2.

More specifically, the pulley 12aa can be rotated counterclockwise about the axis P3 by, e.g., combining the movement of the nut N2a in the direction of the arrow 301 caused by the operation of the motor M2a and the movement of the nut N2b in the direction of the arrow 304 caused by the operation of the motor M2b.

At this time, when the force acting in the direction of the arrow 301 is assumed to be 1, for example, if the motors M2a and M2b are individually driven and controlled such that the force acting in the direction of the arrow 301 is equal to 1 and the force acting in the direction of the arrow 304 is equal to 1−α (where α is a positive number smaller than 1), it is possible to change the counterclockwise rotation amount of the pulley 12aa so that the pulley 12aa is rotated while weakening the tension of the belt T2.

If the motors M2a and M2b are individually driven and controlled so that the force acting in the direction of the arrow 301 is equal to 1 and the force acting in the direction of the arrow 304 is equal to 1+α, it is possible to change the counterclockwise rotation amount of the pulley 12aa so that the pulley 12aa is rotated while strengthening the tension of the belt T2.

In a similar manner to the counterclockwise rotation mentioned above, the pulley 12aa can be rotated clockwise by combining the movement of the nut N2b in the direction of the arrow 303 and the movement of the nut N2a in the direction of the arrow 302.

The tension of the belt T2 can be easily increased by combining the movement of the nut N2a in the direction of the arrow 301 and the movement of the nut N2b in the direction of the arrow 303.

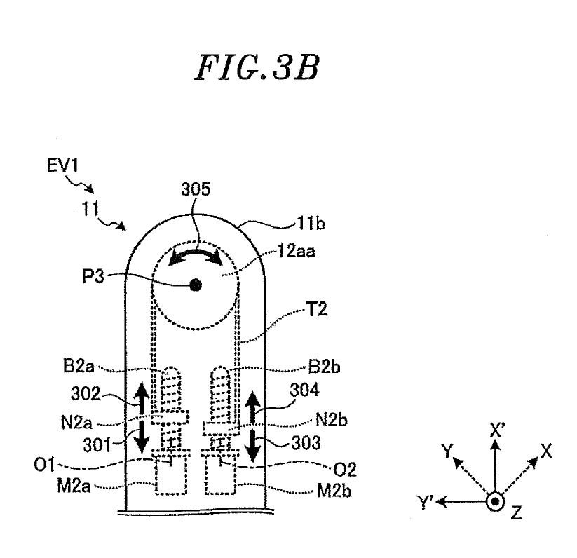

Such independent control of the motors M2a and M2b is performed by the control device 20. The configuration of the control device 20 will now be described with reference to FIG. 4A. FIG. 4A is a block diagram showing the configuration of the control device 20.

In FIG. 4A, the components required to describe the features of the control device 20 are only shown, and general components are not shown.

As shown in FIG. 4A, the control device 20 includes a controller 21 and a storage unit 22. The controller 21 includes an arm drive controller 21a, a hand drive controller 21b and an adjustor 21c. The storage unit 22 stores the transverse sway correction information 22a.

The controller 21 performs the overall control of the control device 20. The arm drive controller 21a performs the drive control of the motor M1 serving as a drive power source of the first arm 11a.

The hand drive controller 21b drives and controls the motors M2a and M2b independently of each other. Based on a correction value for a transverse sway amount previously set in the transverse sway correction information 22a, the adjustor 21c adjusts the drive control of the motors M2a and M2b performed by the hand drive controller 21b.

The storage unit 22 is a memory device such as a hard disk device or a nonvolatile memory and is configured to store the transverse sway correction information 22a.

The transverse sway correction information 22a will now be described with reference to FIG. 4B. FIG. 4B shows one example of the transverse sway correction information 22a. In FIG. 4B, the transverse sway amount of the hand 12 is indicated on the horizontal axis, and the rotation amount is indicated on the vertical axis. The dotted-line curve and the three central arrows correspond to the dotted-line 204 and the arrows 205, 206 and 207 shown in FIG. 2.

The transverse sway correction information 22a is derived by, e.g., evaluation tests conducted in the manufacturing process of the robot 10 and is a set of predetermined correction values corresponding to the transverse sway amounts for the respective rotation amounts.

For example, FIG. 4B illustrates an example in which the transverse sway amount of the hand 12 becomes larger in the minus direction when the rotation amount of the hand 12 is θ/4 (that is, an example in which the rotation of the hand 12 relative to the extensible/retractable arm unit 11 is greatly delayed). In this case, for example, a correction value for correcting the rotation amount of the pulley 12aa or the tension of the belt T2 to the plus direction at such timing is set in the transverse sway correction information 22a.

Accordingly, when the actual rotation amount of the hand 12 is θ/4, the motors M2a and M2b are individually driven and controlled so that the rotation amount of the pulley 12aa or the tension of the belt T2 can be adjusted by the correction value to the plus direction.

FIG. 4B further illustrates an example in which the transverse sway amount of the hand 12 becomes larger in the plus direction when the rotation amount of the hand 12 is 3θ/4 (that is, an example in which the rotation of the hand 12 relative to the extensible/retractable arm unit 11 is greatly advanced). In this case, for example, a correction value for correcting the rotation amount of the pulley 12aa or the tension of the belt T2 to the minus direction at such timing is set in the transverse sway correction information 22a.

Accordingly, when the actual rotation amount of the hand 12 is 3θ/4, the motors M2a and M2b are individually driven and controlled so that the rotation amount of the pulley 12aa or the tension of the belt T2 can be adjusted by the correction value to the minus direction.

The example shown in FIG. 4B is nothing more than one example. As an alternative example, the transverse sway correction information 22a may be the learning information based on the actual transverse sway amounts repeatedly detected during the actual operation of the robot 10. In this case, the transverse sway amounts corresponding to the actual rotation amounts of the hand 12 may be detected by installing a transverse-sway-amount-measuring sensor in, e.g., the tip end portion of the hand 12. The correction values may be successively renewed based on the detected values.

The belt drive device described above can provide the following effects. First of all, the drive power source of the belt T2 for rotating the pulley 12aa is installed close to the hand 12. This helps shorten the length of the belt T2. Accordingly, it is possible to make the power transmission rigidity hard to decrease. Moreover, the belt T2 is directly driven by the motors M2a and M2b. It is therefore possible to secure the power transmission rigidity regardless of the size of the workpiece W, thereby reducing the transverse sway.

The opposite ends of the belt T2 are guided and moved by the ball screws B2a and B2b via the nuts N2a and n2b. Accordingly, it is possible to accurately move the belt T2. This assists in securing the power transmission rigidity regardless of the size of the workpiece W.

The belt T2 can be driven from its opposite ends by the motors M2a and M2b which are driven and controlled independently of each other. This makes it possible to finely adjust the rotation amount of the pulley 12aa and the tension of the belt T2. Accordingly, even if the workpiece W has a large size and the transverse sway tends to grow larger, it is possible to secure the power transmission rigidity to reduce the transverse sway.

Further, the motors M2a and M2b are arranged such that the output shafts O1 and O2 thereof extend along the extension direction of the second arm 11b. It is therefore possible to reduce the thickness of at least the second arm 11b. This assists in reducing the size of the robot 10 and narrowing the operation space.

As described above, the robot arm according to the first embodiment includes the extensible/retractable arm unit 11, the hand (robot hand) 12 and the belt drive device. The extensible/retractable arm unit 11 is extended and retracted in the horizontal direction and is provided with the pulley in the tip end portion thereof. The hand 12 is rotatably connected to the tip end portion of the extensible/retractable arm unit 11 through the pulley. The belt drive device includes the drive power sources arranged close to the hand to directly drive the belt wound around the pulley.

According to the robot arm of the first embodiment, it is therefore possible to secure the power transmission rigidity regardless of the size of the workpiece W, thereby reducing the transverse sway.

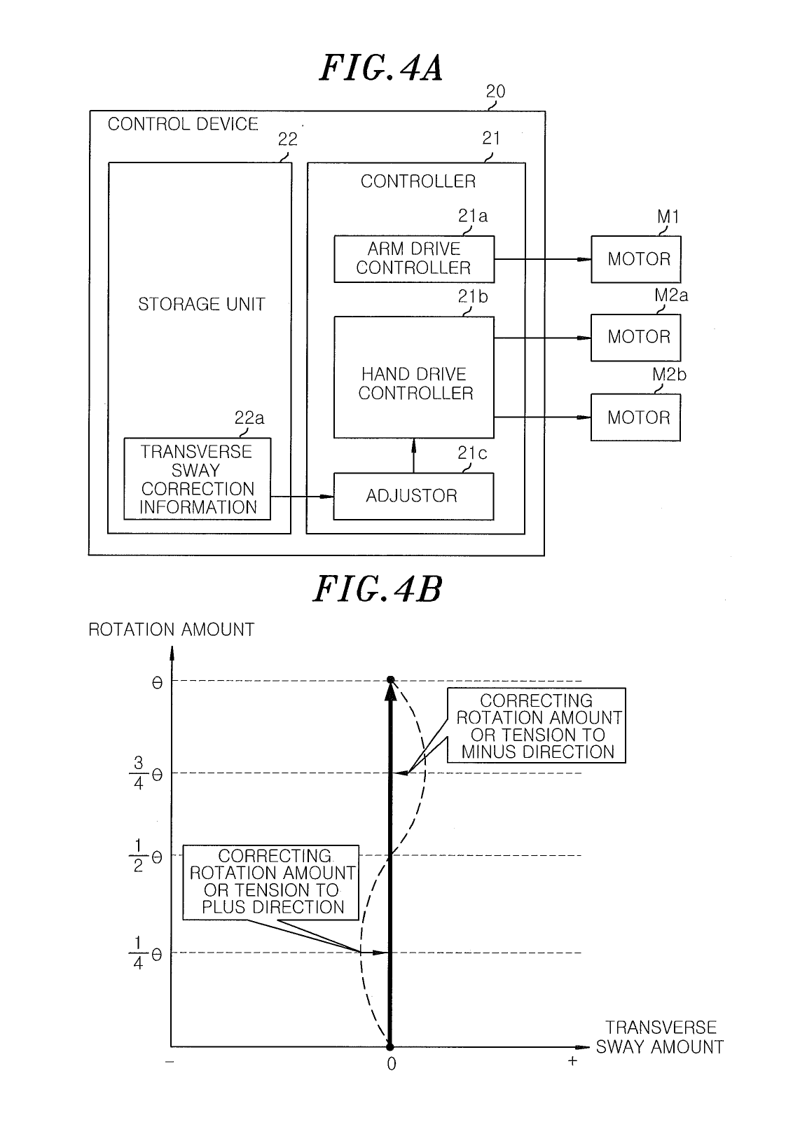

In the first embodiment described above, there has been illustrated a case in which the individual drive power sources are connected to the opposite ends of the belts of the belt drive device and in which the tension of the belt is adjusted by independently controlling the drive power sources. Alternatively, it may be possible to employ a configuration in which an idle pulley is installed. This configuration will be regarded as a second embodiment and will be described below with reference to FIG. 5.

### Second Embodiment

FIG. 5 is a schematic plan view showing an internal configuration of a robot arm according to a second embodiment. Since the internal configuration of an extensible/retractable arm unit 11′ shown in FIG. 5 is only different between the first embodiment and the second embodiment, FIG. 5 merely shows the extensible/retractable arm unit 11′.

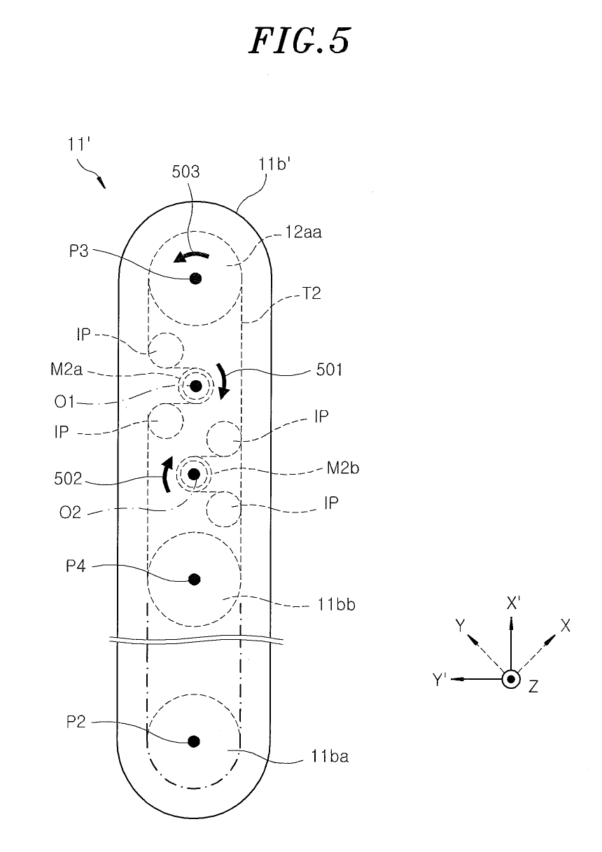

FIG. 5 corresponds to FIG. 3B of the first embodiment. Therefore, description will be focused on the components of the second embodiment differing from those of the first embodiment. In some cases, the same components will be described briefly or redundant description thereof will be omitted. This holds true in a third embodiment to be described later with reference to FIG. 6.

As shown in FIG. 5, the second arm 11b′ of the extensible/retractable arm unit 11′ according to the second embodiment includes a belt drive device in which motors M2a and M2b as drive power sources of a belt T2 are arranged close to a hand 12. The motors M2a and M2b are arranged such that the output shafts O1 and O2 thereof extend along the Z-axis direction in FIG. 5. While not designated by reference symbols, pulleys are respectively connected to the output shafts O1 and O2.

The second arm 11b′ of the extensible/retractable arm unit 11′ further includes an additional pulley 11bb installed as a mate of the pulley 12aa along the extension direction of the second arm 11b′ and configured to rotate about an axis P4. As shown in FIG. 5, the additional pulley 11bb may be replaced by a driven pulley 11ba arranged in the base end portion of the second arm 11b′ to rotate about an axis P2.

Idle pulleys IP are arranged close to the motors M2a and M2b (i.e., in the tip end portion of the second arm 11b′).

As shown in FIG. 5, a belt T2 is stretched to travel around the pulley 12aa and the additional pulley 11bb via the pulley of the motor M2a, the pulley of the motor M2b and the idle pulleys IP.

With this configuration, by rotating the pulleys of the motors M2a and M2b clockwise (see the arrows 501 and 502 in FIG. 5), it is possible to rotate the pulley 12aa counterclockwise about the axis P3 (see the arrow 503 in FIG. 5) while maintaining the tension of the belt T2 with the idle pulleys IP. Further, the pulley 12aa can be rotated clockwise by rotating the motors M2a and M2b in the counterclockwise direction.

The robot arm according to the second embodiment can provide the following effects. First of all, the drive power sources are installed close to the hand 12, and the additional pulley 11bb is arranged adjacent to the drive power sources. This makes it possible to shorten the length of the belt T2 stretched between the pulley 12aa and the additional pulley 11bb. Accordingly, it is possible to make the power transmission rigidity hard to decrease.

Since the pulley 12aa can be rotated while maintaining the tension of the belt T2 with the idle pulleys IP, it is possible to secure the power transmission rigidity regardless of the size of the workpiece, thereby reducing the transverse sway.

Inasmuch as the belt T2 wound between the pulley 12aa and the additional pulley 11bb can be repeatedly rotated, it is possible, if necessary, to perform the operation of swinging the hand 12.

As shown in FIG. 5, the motors M2a and M2b as drive power sources are arranged between the pulley 12aa and the additional pulley 11bb. It is therefore possible to realize a compact configuration of the belt drive device.

In the example shown in FIG. 5, the motors M2a and M2b are arranged such that the output shafts O1 and O2 thereof extend along the Z-axis direction. Alternatively, the output shafts O1 and O2 may be installed to extend along the X′-axis direction in FIG. 5, i.e., along the extension direction of the second arm 11b′. In this case, the rotation direction of the output shafts O1 and O2 can be converted through the use of gears or the like.

In this case, it is possible to reduce the thickness of the second arm 11b′. This assists in reducing the size of the robot 10 and narrowing the operation space.

In the first embodiment described above, there has been illustrated a case in which the individual drive power sources are connected to the opposite ends of the belt of the belt drive device and in which the drive power sources are controlled independently of each other. Alternatively, it may be possible to employ a configuration in which a drive power source is installed only at one end of the belt. This configuration will be regarded as a third embodiment and will be described below with reference to FIG. 6.

### Third Embodiment

FIG. 6 is a schematic plan view showing an internal configuration of a robot arm according to a third embodiment. Since the internal configuration of an extensible/retractable arm unit 11″ shown in FIG. 6 is different between the first embodiment and the third embodiment, FIG. 6 merely shows the extensible/retractable arm unit 11″.

As shown in FIG. 6, the second arm 11″ of the extensible/retractable arm unit 11″ according to the third embodiment includes a belt drive device in which a single motor M2a as a drive power source of a belt T2 is arranged close to a hand 12.

The motor M2a is arranged such that the output shaft O1 thereof extends along the extension direction of the second arm 11b″ (i.e., along the X′-axis direction in FIG. 6). A ball screw B2a and a pulley 11bc are connected to the output shaft O1.

A ball screw B2b having a reverse thread direction is installed side by side with respect to the ball screw B2a. A pulley 11bd is connected to the ball screw B2b. The pulley 11bd is connected to the pulley 11bc through a belt T, whereby the ball screw B2b can rotate following the rotation of the ball screw B2a.

In the configuration described above, upon driving the motor M2a, the nuts N2a and N2b always move in the opposite direction from each other, thereby rotating the pulley 12aa in one direction.

More specifically, when the motor M2a moves the nut N2a in the direction of the arrow 601 as shown in FIG. 6, the ball screw B2b is passively rotated to move the nut N2b in the direction of the arrow 602, consequently rotating the pulley 12aa counterclockwise about the axis P3. The pulley 12aa can be rotated clockwise by reversely rotating the motor M2a.

The robot arm according to the third embodiment can provide the following effects. First of all, the belt T2 may have a short length because the drive power source of the belt T2 for rotating the pulley 12aa is installed close to the hand 12. It is therefore possible to make the reduction of the power transmission rigidity hard to occur. Since the belt T2 is directly driven by the motor M2a, it is possible to secure the power transmission rigidity regardless of the size of the workpiece W, thereby reducing the transverse sway.

The opposite ends of the belt T2 are guided and moved by the ball screws B2a and B2b via the nuts N2a and n2b. Accordingly, it is possible to accurately move the belt T2 while maintaining the tension of the belt T2. This assists in securing the power transmission rigidity regardless of the size of the workpiece W.

The motor M2a is arranged such that the output shaft O1 thereof extends along the extension direction of the second arm 11b″. It is therefore possible to reduce the thickness of at least the second arm 11b″. This assists in reducing the size of the robot 10 and narrowing the operation space.

(Other Modification)

The respective embodiments described above are common in that they include the motor or motors for directly driving the belt that rotates the hand. Taking advantage of this aspect, there may be provided a belt disconnection sensing mechanism for sensing the disconnection of the belt.

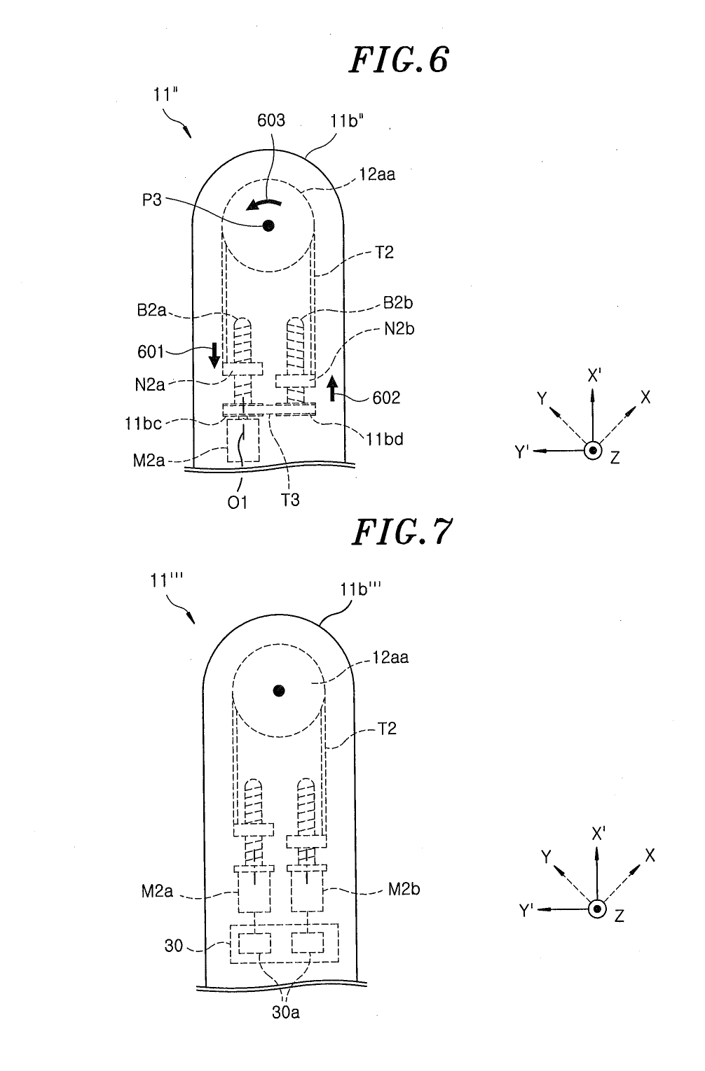

This modification will be described with reference to FIG. 7. FIG. 7 is a schematic plan view showing a second arm unit 11′″ including a configuration of a belt disconnection sensing mechanism 30. FIG. 7 corresponds to FIG. 3B of the first embodiment.

As shown in FIG. 7, the belt disconnection sensing mechanism 30 includes load detecting units 30a respectively connected to the motors M2a and M2b. The load detecting units 30a are units for detecting changes of loads acting on the motors M2a and M2b.

In a state in which the belt T2 is not disconnected, a load acts at least on the motors M2a and M2b for directly driving the belt T2, regardless of whether the hand 12 is in a stopped state or in an operating state.

Taking advantage of such aspect, when the load detecting units 30a detect that the loads acting on the motors M2a and M2b are substantially simultaneously changed close to a load-free state (i.e., a state in which the loads are equal to zero), the belt disconnection sensing mechanism 30 senses it as disconnection of the belt T2.

As a result, it is possible to quickly detect and cope with a situation where the hand 12 becomes uncontrollable due to the belt disconnection. This indirectly assists in securing the power transmission rigidity and reducing the transverse sway.

While the dual-arm robot has been described by way of example in the respective embodiments described above, this is not intended to limit the number of arms of the robot. The present disclosure may be applied to a single arm robot or a robot having more than two arms.

In the respective embodiments described above, there has been described by way of example a case where the extensible/retractable arm unit is formed by interconnecting two arms. However, this is not intended to limit the number of the arms connected to one another.

In the respective embodiments described above, the robot is installed on the running carriage to perform the running axis operation. However, the kind of the running mechanism is not limited as long as the robot can move along a predetermined track.

In the respective embodiments described above, there has been described by way of example a case where the workpiece serving as a transfer target object is a glass substrate. However, this is not intended to limit the kind of the workpiece.

In the respective embodiments described above, there has been described by way of example a case where the robot is a substrate transfer robot. However, this is not intended to limit the use of the robot. It is only necessary that the robot is a horizontal articulated robot.

Other effects and modified examples can be readily derived by those skilled in the relevant art. For that reason, the broad aspect of the present disclosure is not limited to the specific disclosures and the representative embodiments shown and described above. Accordingly, it should be understood by those skilled in the art that various modifications, combinations, sub-combinations and alterations may occur depending on design requirements and other factors insofar as they are within the scope of the appended claims or the equivalents thereof.

What is claimed is:

1. A robot arm, comprising:
an extensible/retractable arm unit configured to extend and retract in a horizontal direction and provided with a pulley arranged in a tip end portion thereof;
a robot hand rotatably connected to the tip end portion of the extensible/retractable arm unit through the pulley; and
a belt drive device including one or more drive power sources, which are arranged close to the robot hand and configured to directly drive a belt wound around the pulley.

2. The robot arm of claim 1, wherein the extensible/retractable arm unit includes a first arm having a base end portion rotatably connected to an arm base, and a second arm having a base end portion rotatably connected to a tip end portion of the first arm and a tip end portion to which the robot hand is rotatably connected, and
wherein the belt drive device is arranged in the second arm.

3. The robot arm of claim 2, wherein the belt drive device includes one or more motors each serving as a drive power source, and
wherein each of the motors is arranged such that an output shaft thereof extends along an extension direction of the second arm.

4. The robot arm of claim 3, wherein a ball screw is connected to the output shaft of each of the motors, and
wherein the belt is connected to each of the motors by an end portion thereof being fixed to a nut of the ball screw.

5. The robot arm of claim 3, wherein the belt drive device includes a first motor of the motors connected to one end of the belt and a second motor of the motors connected to the other end of the belt, and
wherein a tension of the belt or a rotation amount of the pulley is adjusted by independently driving and controlling the first motor and the second motor.

6. The robot arm of claim 4, wherein the belt drive device includes a first motor of the motors connected to one end of the belt and a second motor of the motors connected to the other end of the belt, and
wherein a tension of the belt or a rotation amount of the pulley is adjusted by independently driving and controlling the first motor and the second motor.

7. The robot arm of claim 2, wherein the belt drive device includes a first motor and a second motor each serving as a drive power source, a plurality of idle pulleys arranged adjacent to the first motor and the second motor, and an additional pulley provided as a mate of the pulley along the extension direction of the second arm,
wherein the first motor and the second motor are arranged between the pulley and the additional pulley, and
wherein the belt interconnects the pulley and the additional pulley such that the belt travels around the pulley and the additional pulley via an output shaft of the first motor, an output shaft of the second motor and the idle pulleys.

8. The robot arm of claim 2, wherein the belt drive device includes a single motor serving as a drive power source, the motor being arranged such that an output shaft thereof extends along an extension direction of the second arm, a first ball screw connected to an output shaft of the motor and one end of the belt, and a second ball screw having a thread direction opposite to a thread direction of the first ball screw, the second ball screw being configured to rotate following a rotation of the first ball screw and being connected to the other end of the belt.

9. The robot arm of claim 1, further comprising:
a load detecting unit configured to detect a change of a load acting on each of the drive power sources; and
a belt disconnection sensing mechanism configured to sense a disconnection of the belt when the load detecting unit detects that the drive power sources are substantially simultaneously changed close to a load-free state.

10. The robot arm of claim 2, further comprising:
a load detecting unit configured to detect a change of a load acting on each of the drive power sources; and
a belt disconnection sensing mechanism configured to sense a disconnection of the belt when the load detecting unit detects that the drive power sources are substantially simultaneously changed close to a load-free state.

11. The robot arm of claim 3, further comprising:
a load detecting unit configured to detect a change of a load acting on each of the drive power sources; and
a belt disconnection sensing mechanism configured to sense a disconnection of the belt when the load detecting unit detects that the drive power sources are substantially simultaneously changed close to a load-free state.

12. The robot arm of claim 4, further comprising:
a load detecting unit configured to detect a change of a load acting on each of the drive power sources; and
a belt disconnection sensing mechanism configured to sense a disconnection of the belt when the load detecting unit detects that the drive power sources are substantially simultaneously changed close to a load-free state.

13. A robot comprising the robot arm of claim 1.

14. A robot comprising the robot arm of claim 2.

15. A robot comprising the robot arm of claim 3.

16. A robot comprising the robot arm of claim 4.

17. A method of operating a robot provided with a robot arm which includes an extensible/retractable arm unit configured to extend and retract in a horizontal direction and provided with a pulley arranged in a tip end portion thereof, a robot hand rotatably connected to the tip end portion of the extensible/retractable arm unit through the pulley, and a belt drive device including a first motor connected to one end of the belt and a second motor connected to the other end of the belt, which are arranged close to the robot hand to directly drive a belt wound around the pulley, the method comprising:
adjusting a tension of the belt or a rotation amount of the pulley by independently driving and controlling the first motor and the second motor based on a correction value set in proportion to a transverse sway amount of the robot hand.
